(19) United States
(12) Patent Application Publication
(10) Pub. No.: US 2024/0186453 A1
(43) Pub. Date: Jun. 6, 2024

(54) LIGHT-EMITTING DEVICE AND LIGHTING APPARATUS

(71) Applicant: XIAMEN SAN’AN OPTOELECTRONICS CO., LTD., Xiamen (CN)

(72) Inventors: Gong CHEN, Xiamen (CN); Jianbin CHEN, Xiamen (CN); Yashu ZANG, Xiamen (CN); Bin JIANG, XIamen (CN); Chung-Yin CHANG, Xiamen (CN); Shaohua HUANG, Xiamen (CN); Weichun TSENG, Xiamen (CN)

(21) Appl. No.: 18/524,643

(22) Filed: Nov. 30, 2023

(30) Foreign Application Priority Data
Dec. 2, 2022 (CN) 202211541638.7

(51) Int. Cl. H01L 33/38; H01L 33/20

(52) U.S. Cl. CPC H01L 33/38; H01L 33/20

(57) ABSTRACT

A light-emitting device includes a semiconductor laminate, a first electrode and a second electrode. The semiconductor laminate has a mesa surface, an upper surface, a connecting surface that connects the upper surface and the mesa surface, and a lower surface opposite to the mesa surface and the upper surface. The semiconductor laminate includes a first semiconductor layer, an active layer, and a second semiconductor layer disposed in such order in a direction from the lower surface to the upper surface. The semiconductor laminate has at least one trench that extends from the mesa surface into the first semiconductor layer. The first electrode is electrically connected to the first semiconductor layer and formed on the mesa surface, and has an extending portion that extends into the trench. The second electrode is electrically connected to the second semiconductor layer and formed on the upper surface.

### CROSS-REFERENCE TO RELATED APPLICATION

This application claims priority to Chinese Invention Patent Application No. CN 202211541638.7, filed on Dec. 2, 2022, which is incorporated herein by reference in its entirety.

### FIELD

The disclosure relates to a light-emitting device and a lighting apparatus.

### BACKGROUND

Light-emitting diodes (LEDs) are semiconductor light-emitting devices typically made of a semiconductor material such as GaN, GaAs, GaP, GaAsP, etc., and include a PN junction for light emitting. LEDs offer advantages such as high luminous intensity, energy efficiency, compact form factors, long lifespan, etc., and currently are considered to be one of the most promising light sources. LEDs have been widely utilized in various applications, e.g., lighting apparatus, surveillance command systems, high-definition broadcasting, high-end cinema, office displays, conference interactions, and virtual reality.

In recent years, ultraviolet LEDs, particularly deep-ultraviolet LEDs, have attracted significant public interest due to their substantial application potential and have subsequently emerged as a new focal point of research. Light-extraction efficiency of deep-ultraviolet LEDs is of paramount importance. Ultraviolet LEDs generally include Group III nitride semiconductor materials having an aluminum (Al) component. However, the Al-containing nitride semiconductor materials have high electrical resistivity, and, when used as a material for an n-type semiconductor layer of the LEDs, may cause low injection efficiency of charge carriers and current crowding especially at corner portions of an electrode.

### SUMMARY

Therefore, an object of the disclosure is to provide a light-emitting device and a lighting apparatus that can alleviate at least one of the drawbacks of the prior art.

According to one aspect of the disclosure, the light-emitting device includes a semiconductor laminate, a first electrode and a second electrode. The semiconductor laminate has a mesa surface, an upper surface, a connecting surface that connects the upper surface and the mesa surface, and a lower surface opposite to the mesa surface and the upper surface. The semiconductor laminate includes a first semiconductor layer, an active layer, and a second semiconductor layer disposed in such order in a direction from the lower surface to the upper surface. Furthermore, the semiconductor laminate has at least one trench that extends from the mesa surface into the first semiconductor layer. The first electrode is electrically connected to the first semiconductor layer and formed on the mesa surface, and has an extending portion that extends into the trench. The second electrode is electrically connected to the second semiconductor layer and formed on the upper surface.

According to another aspect of the disclosure, the lighting apparatus includes the light-emitting device according to the disclosure.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 shows a schematic top view of an embodiment of a light-emitting device according to the present disclosure.

FIG. 2A shows a schematic cross-sectional view of the light-emitting device of FIG. 1.

FIG. 2B is an enlarged view of a portion 100 shown in FIG. 2A.

FIG. 3 is a schematic cross-sectional view of the light-emitting device taken along line A-A′ in FIG. 1.

FIG. 4 is a schematic cross-sectional view of the light-emitting device taken along line B-B′ in FIG. 1.

FIG. 5 to FIG. 8 show schematic top views illustrating different configurations of a trench formed in an embodiment of the light-emitting device.

FIG. 9 shows a schematic cross-sectional view of an embodiment of a flip-chip light-emitting device according to the present disclosure.

FIG. 10 illustrates a schematic cross-sectional view of a variation of the light-emitting device according to the embodiment of FIG. 2A.

FIG. 11 shows a schematic cross-sectional view of another embodiment of the light-emitting device according to the present disclosure.

FIG. 12 shows a schematic cross-sectional view of a yet another embodiment of the light-emitting device according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

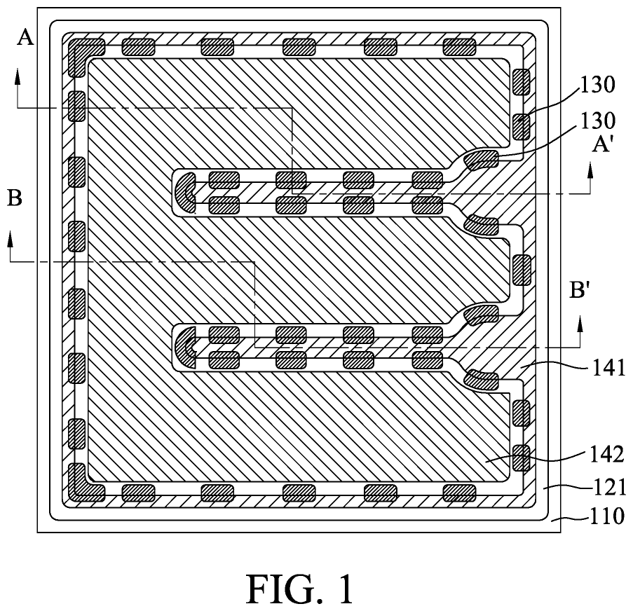

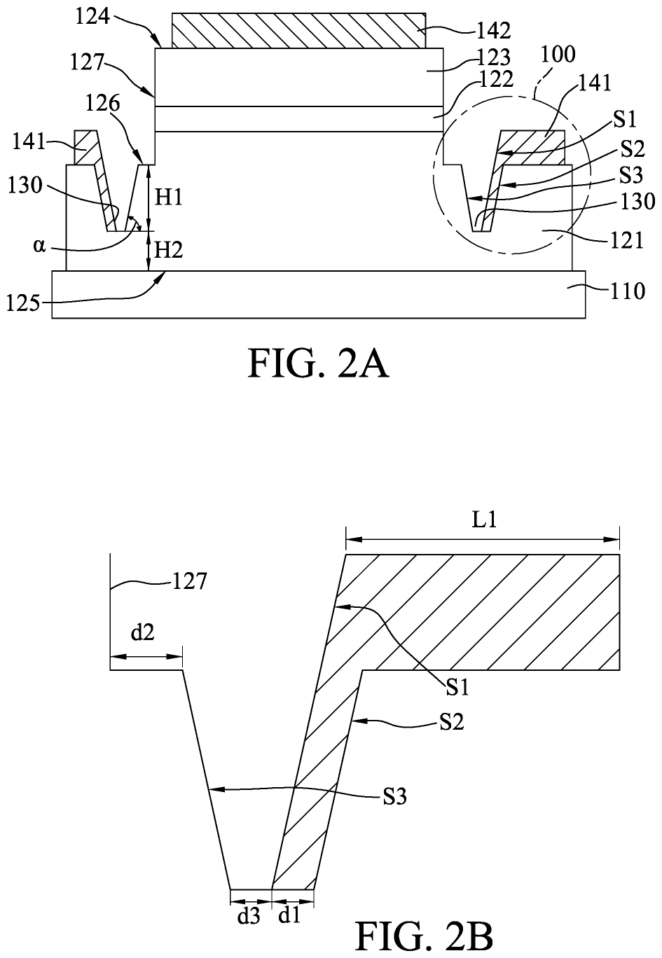

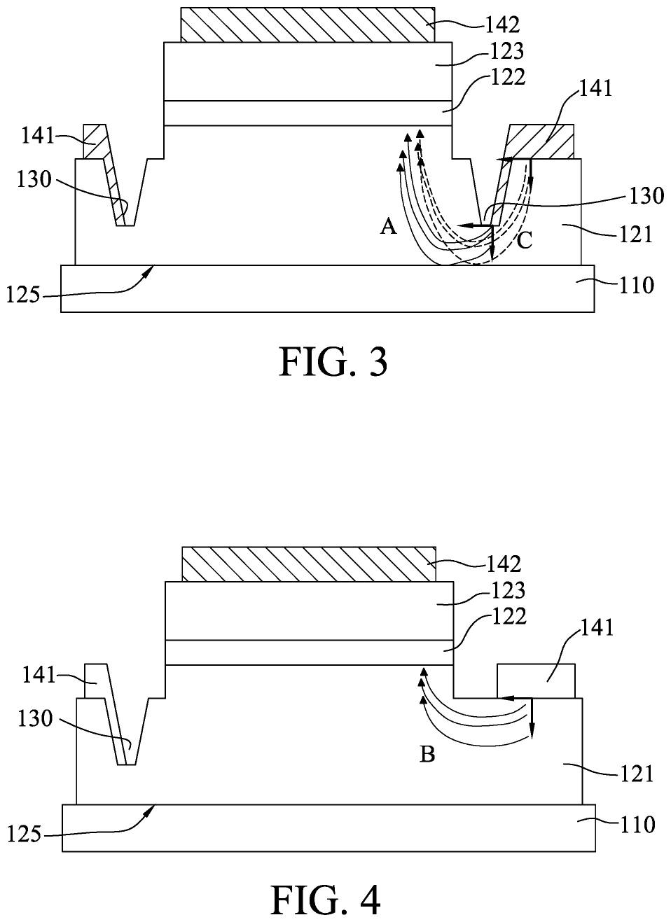

FIG. 1 to FIG. 4 illustrate an embodiment of a light-emitting device according to the present disclosure. FIG. 1 shows a schematic top view of the light-emitting device; FIG. 2A shows a schematic cross-sectional view of the light-emitting device of FIG. 1; FIG. 2B is an enlarged view of a portion 100 shown in FIG. 2A; FIG. 3 is a schematic cross-sectional view of the light-emitting device taken along line A-A′ in FIG. 1; and FIG. 4 is a schematic cross-sectional view of the light-emitting device taken along line B-B′ in FIG. 1.

As shown in FIG. 2A, the light-emitting device may include a substrate 110, a semiconductor laminate 120 disposed on the substrate 110, a first electrode 141 and a second electrode 142.

The substrate 110 may be an insulating substrate. In certain embodiments, the substrate 110 may be a transparent substrate or a semi-transparent substrate that may allow light emitted from the semiconductor laminate 120 to pass through the substrate 110. For example, the substrate 110 may be any one of a sapphire flat substrate, a sapphire patterned substrate, a silicon substrate, a silicon carbide substrate, a gallium nitride substrate, and a glass substrate.

In some embodiments, the substrate 110 may be a composite substrate that has a base structure and a patterned structure formed on the base structure. The patterned structure may be a single-layer structure or a multi-layer structure and includes at least one light extraction layer. The light extraction layer has a refractive index lower than a refractive index of the base structure. The light extraction layer has a height greater than half of a height of the patterned structure. Such configuration is beneficial to improving light emission efficiency of the light-emitting device. In certain embodiments, the patterned structure is composed of a plurality of dome-shaped structures. The light extraction layer may include a material having a refractive index of less than 1.6, such as silicon dioxide. In some embodiments, the substrate 110 may be thinned or removed for forming a thin film chip.

The semiconductor laminate 120 has a mesa surface 126, an upper surface 124, a connecting surface 127 that connects the upper surface 124 and the mesa surface 126, and a lower surface 125 opposite to the mesa surface 126 and the upper surface 124. The semiconductor laminate 120 includes a first semiconductor layer 121, an active layer 122, and a second semiconductor layer 123 disposed in such order in a direction from the lower surface 125 to the upper surface 124. In this embodiment, the mesa surface 126 is a surface of the first semiconductor layer 121 that is not covered by the active layer 122. The upper surface 124 is a surface of the second semiconductor layer 123.

The first semiconductor layer 121 is formed on the substrate 110 and may be an n-type semiconductor layer that provides electrons to the active layer 122 when voltage is applied. In some embodiments, the first semiconductor layer 121 includes an n-type doped nitride layer. The n-type doped nitride layer may include one or more Group IV elements as an n-type dopant. The n-type dopant may include one of Si, Ge, Sn, or combinations thereof. In this embodiment, the first semiconductor layer 121 includes Al, which is conducive for the light-emitting device to emit ultraviolet light. In some embodiments, the light-emitting device may further include a buffer layer that is disposed between the first semiconductor layer 121 and the substrate 110 to alleviate lattice mismatch therebetween. The buffer layer may include an unintentionally doped AlN layer (un-doped AlN, u-AlN for short) or an unintentionally doped AlGaN layer (un-doped AlGaN, u-AlGaN for short). In other embodiments, the first semiconductor layer 121 may bond to the substrate 110 through a bonding layer.

The active layer 122 may be a quantum well (QW) structure. In some embodiments, the active layer 122 may be a multiple quantum well (MQW) structure including quantum well sub-layers and quantum barrier sub-layers that are alternately arranged in a repetitive manner. In other words, the multiple quantum well structure includes a plurality of layer units each being composed of one of the quantum well sub-layers and one of the quantum barrier sub-layers. The layer units of the multiple quantum well structure may each be GaN/AlGaN, InAlGaN/InAlGaN or InGaN/AlGaN. In addition, a constitution and a thickness of each of the quantum well sub-layers in the active layer 122 may determine a wavelength of the light generated by the semiconductor laminate 120. To improve light emission efficiency of the active layer 122, the thickness of each of the quantum well sub-layers, the number and thicknesses of the layer units and/or other features of the active layer 122 may be adjusted. In particular, by adjusting the constitutions of the quantum well sub-layers, the active layer 122 may emit different lights such as ultraviolet light, blue light, green light, etc. In this embodiment, the light-emitting device emits light having a wavelength ranging from 200 nm to 420 nm, i.e., the active layer 122 emits light having a wavelength ranging from 200 nm to 420 nm.

The second semiconductor layer 123 may be a p-type semiconductor layer that provides holes to the active layer 122 when voltage is applied. In some embodiments, the second semiconductor layer 123 includes a p-type doped nitride layer. The p-type doped nitride layer may include one or more Group Il elements as a p-type dopant. The p-type dopant may include one of Mg, Zn, Be, or combinations thereof.

The first semiconductor layer 121 and the second semiconductor layer 123 may each be a single-layer structure, but not limited thereto. In the present disclosure, the first semiconductor layer 121 and the second semiconductor layer 123 may each be a multi-layer structure that has multiple layers containing different constitutions and that may further include a super lattice layer. In addition, the semiconductor laminate 120 in the light-emitting device of the disclosure is not limited to the aforementioned configuration, and other types of semiconductor laminate 120 may be utilized based on actual requirements. For example, in other embodiments, the first semiconductor layer 121 may be doped with a p-type dopant, and the second semiconductor layer 123 may be doped with an n-type dopant. In other words, the first semiconductor layer 121 may be a p-type semiconductor layer, and the second semiconductor layer 123 may be an n-type semiconductor layer.

Furthermore, the semiconductor laminate 120 has at least one trench 130 that extends from the mesa surface 126 into the first semiconductor layer 121. In this embodiment, the first electrode 141 may have a strip portion. The first electrode 141 is electrically connected to the first semiconductor layer 121, so that a current injected from the first electrode 141 may be injected directly into the first semiconductor layer 121 through the trench-defining wall (e.g., the first region (S2)), thereby reducing operating voltage and improving stability of the light-emitting device. In this embodiment, the first electrode 141 is formed on the mesa surface 126 and has an extending portion that extends into the trench 130. Such configuration may modulate current flow to mitigate current crowding, thereby facilitating current spread, lowering operating voltage, and enhancing brightness of the light-emitting device. Specifically, referring to FIG. 3, around the extending portion of the first electrode 141 that extends into the trench 130, current flow paths include a path A (in solid line) and a path C (in dashed line). The path A shows the current flow path starting at a position within the trench 130 from the extending portion of the first electrode 141 to the active layer 122. The path C shows the current flow path starting at the mesa surface 126 from the first electrode 141 to the active layer 122. The path C is longer than the path A. Therefore, there is a time difference in the flow of charge carriers between the path A and the path C, which may reduce current crowding. Furthermore, with such a configuration, the first electrode 141 has an increased contact area with the first semiconductor layer 121, and an increased volume which may reduce the operating voltage. In the present embodiment, the semiconductor laminate includes a plurality of the trenches 130 that are spaced apart from each other. In FIGS. 1 and 4, at a portion of the first electrode 141 that is between two adjacent trenches 130 (i.e., where no trench 130 is located between the portion of the first electrode 141 and the first semiconductor layer 121), a current flow path B from the first electrode 141 to the active layer 122 is shown (see FIG. 4). In other words, the light-emitting device according to the present disclosure has three current flow paths, the path A, the path B, and the path C for current to flow from the first electrode 141 to the active layer 122, while a conventional light-emitting device without the trench 130 may only have the path B. As compared to the conventional light-emitting device, the configuration of the light-emitting device according to the present disclosure may regulate the current flow by providing alternative paths for the current to flow at different portions, thereby reducing current crowding. In certain embodiments, referring to FIG. 2B, each of the trenches 130 is defined by a trench-defining wall. The trench-defining wall has a first region (S2) which is away from the connecting surface 127 and covered by the extending portion of the first electrode 141. The extending portion of the electrode 141 has an extending wall (S1) away from the trench-defining wall. The first electrode 141 has an upper surface that is opposite to the mesa surface 126 and that is connected to the extending wall (S1). As shown in FIG. 2B, the extending wall (S1) of the electrode 141 is separated from the first region (S2) of the trench-defining wall by a distance (d1) that is less than a width (L1) of the upper surface of the first electrode 141. That is, some portions of the first electrode 141 are located within the trenches 130 and some portions of the first electrode 141 are located on the mesa surface 126. Such a configuration may achieve diversion of current flow so as to further reduce current crowding.

In the present embodiment, as shown in FIG. 2B, the trench-defining wall has a second region (S3) that is closer to the connecting surface 127 than the first region (S2). The second region (S3) is spaced apart from the connecting surface 127 by a distance (d2). This may ensure that the upper surface 124 would not be damaged during the formation of the trenches 130. In certain embodiments, the distance (d2) may be 1 μm or more, for example, range from 1 μm to 10 μm. It should be noted that the distance (d2) should not be excessively large which may undesirably increase the distance for the current to flow through.

In this embodiment, the second region (S3) is spaced apart from the extending wall (S1) of the first electrode 141 by a distance (d3). In certain embodiments, the distance (d3) may be 1 μm or more, for example, ranging from 1 μm to 10 μm. It should be noted that the distance (d3) should not be excessively large which may undesirably increase the distance for the current to flow through.

As shown in FIG. 2A, each of the trenches 130 extends from the mesa surface 126 into the first semiconductor layer 121 by a depth (H1). Each of the trenches 130 has a bottom that is distal from the mesa surface 126. The bottom is separated from the lower surface 125 of the semiconductor laminate 120 by a distance (H2) that is ⅕ to ½ of a thickness of the first semiconductor layer 121. If the distance (H2) is excessively large, the charge carriers will congregate near the mesa surface 126, leading to poor current spread. This will cause current crowding and reduce the injection efficiency of the charge carriers. If the distance (H2) is excessively small, the bottoms of the trenches 130 are very close to the lower surface 125. This will cause congestion when the charge carriers reach the bottoms of the trenches 130 and cause current crowding, and reduce the injection efficiency of the charge carriers, which is detrimental to the spreading of the charge carriers. Furthermore, in some embodiments, the depth (H1) is greater than 100 nm, for example ranging from 600 nm to 1200 nm, so as to ensure diversion of the current flow and improve injection efficiency of the charge carriers.

In some embodiments, a mesa height, or a distance from the mesa surface 126 to the lower surface 125 (i.e. a sum of the depth (H1) and the distance (H2)), is greater than or equal to half of the thickness of the first semiconductor layer 121. If the mesa height is excessively small, the charge carriers will congregate under the mesa surface 126, and the spreading of the charge carriers will be negatively affected leading to current crowding and thus reducing the injection efficiency of the charge carriers. It should be noted that the mesa height may be 60% to 95% of the thickness of the first semiconductor layer 121.

In some embodiments, when viewing from above the light-emitting device, as shown in FIG. 1, a projection of each of the trenches 130 on the lower surface 125 may have a shape of a square, a circle, or an ellipse. The projection of each of the trenches 130 having a shape that closely resembles a square may facilitate the positioning of the first electrode 141 within the trench 130. Each of the trenches 130 has an opening at the mesa surface 126. The opening has a width that ranges from 1 μm to 50 μm.

In some embodiments, in consideration of issues of light reflection and the current state of manufacturing technology, for each of the trenches 130, the opening at the mesa surface 126 is greater in size than the bottom. This configuration may improve performance of reflection and enhance the light emission efficiency of the light-emitting device. In certain embodiments, each of the trenches 130 has a cross section in the direction from the lower surface 125 to the upper surface 124, and the cross section has a trapezoidal shape. The trench-defining wall has an inclined angle (a) that is less than 90 degrees, for example, ranging from 20 degrees to 50 degrees. Such a configuration further enhances the light emission efficiency of the light-emitting device. When the first electrode 141 is being formed, if the trench-defining wall of each of the trench 130 are vertical (i.e. the inclined angle is 90 degrees), there will be uneven deposition of the first electrode 141 at corners of the trench 130.

In some embodiments, when viewing from above the light-emitting device, a projection of the first electrode 141 on the lower surface 125 partially overlaps the projection of each of the trenches 130 on the lower surface 125. An overlapping area where the projection of the first electrode 141 overlaps the projections of the trenches 130 is 5% to 70%, for example 15% to 50%, of the projection of the first electrode 141. Furthermore, in some embodiments, a total area of the projections of the trenches 130 on the lower surface 125 is 5% to 60% of an area of the mesa surface 126. That is, the total area of the projections of the trenches 130 on the lower surface 125 is 5% to 60% of an area of a projection of the mesa surface 126 on the lower surface 125. This configuration may ensure uniform current distribution. If the trenches 130 collectively occupy an excessively large area, it may lead to uneven current distribution and uneven light emission. In certain embodiments, the total area of the projections of the trenches 130 on the lower surface 125 is 10% to 40% of the area of the mesa surface 126.

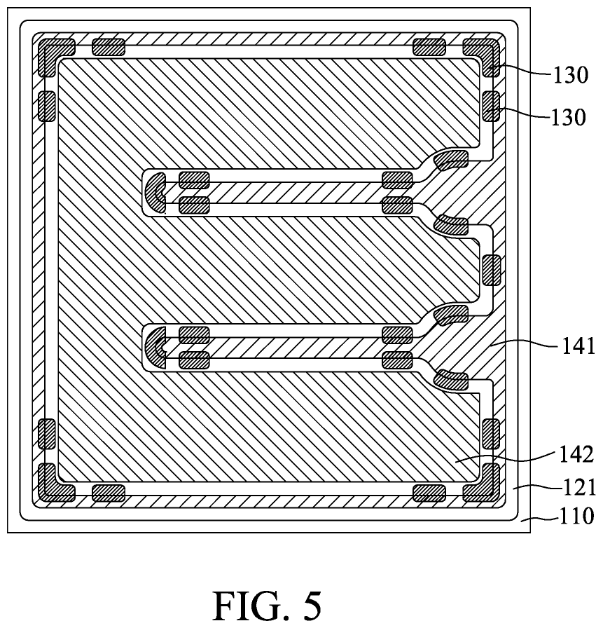

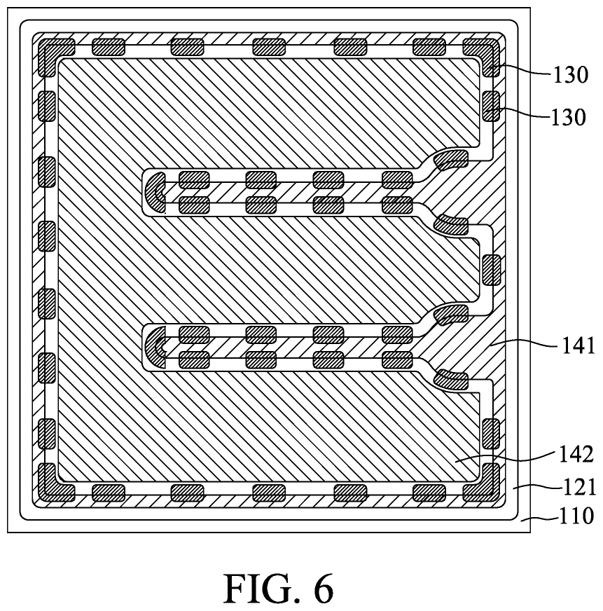

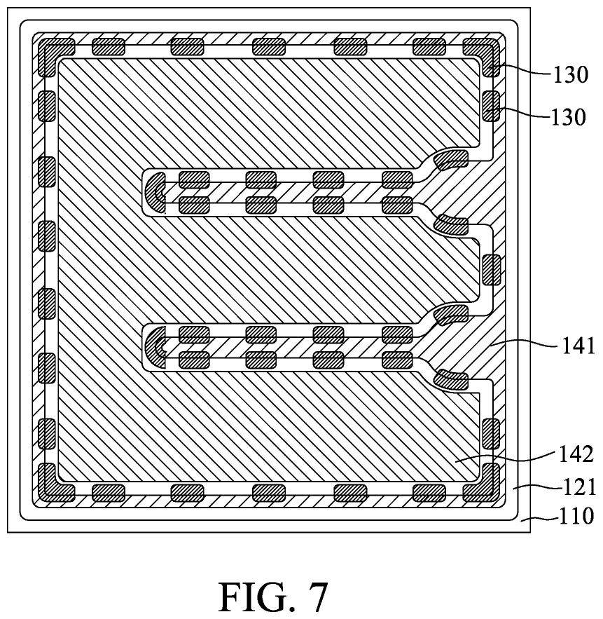

In the embodiment where the trenches 130 are formed to be spaced apart from each other as shown in FIG. 1, the mesa surface 126 may have a larger area, which is conducive for enhancing the light emission efficiency of the light-emitting device. In some embodiments, when viewing the first electrode 141 and the trench 130 from above the light-emitting device, the first electrode 141 has a corner portion, and the trenches 130 arranged along the first electrode 141 are more densely arranged near the corner portion. This may effectively alleviate current crowding that is more likely to occur at the corner portion of the first electrode 141, thereby effectively enhancing the injection efficiency of the charge carriers of the light-emitting device. FIG. 5 to FIG. 7 illustrate different configurations of the trench(es) 130 of the light-emitting device. Since current crowding is more likely to occur at the corner portion of the first electrode 141, the trench(es) 130 may be only positioned near the corner portion, as shown in FIG. 5. This configuration effectively alleviates current crowding at the corner portion of the first electrode 141 while preserving larger area for the mesa surface 126. Furthermore, providing a larger light-emitting area (not shown) may further improve the light emission efficiency of the light-emitting device. In some embodiments, the trenches 130 may be uniformly spaced apart from each other, distributed with progressively narrowing spacing or distributed with progressively widening spacing. FIG. 6 illustrates that the trenches 130 are arranged along the first electrode 141, and are spaced increasingly further apart as the trenches 130 are positioned progressively further away from the at least one corner portion of the first electrode 141. That is, two adjacent ones of the trenches 130 at a position near the corner portion have a narrower spacing, while two adjacent ones of the trenches 130 at a position away from the corner portion have a wider spacing. This configuration likewise alleviates current crowding at the corner position of the first electrode 141 while preserving larger area for the mesa surface 126. FIG. 7 illustrates the trenches 130 that are spaced apart from each other in two different uniform spacings respectively at the position near the corner position and at the position away from the corner position. Specifically, the trenches 130 at the position near the corner portion are spaced apart from each other by a narrower uniform spacing, while the trenches 130 at the position away from the corner portion are spaced apart from each other by a wider uniform spacing. At the position near the corner portion, two adjacent ones of the trenches 130 are spaced apart by a distance ranging from, e.g., 1 μm to 40 μm. At the position away from the corner portion, two adjacent ones of the trenches 130 are spaced apart by a distance ranging from, e.g., 5 μm to 100 μm. In certain embodiments, at the position near the corner portion, two adjacent ones of the trenches 130 are spaced apart by a distance ranging from 10 μm to 30 μm, and at the position away from the corner portion, two adjacent ones of the trenches 130 are spaced apart by a distance ranging from 20 μm to 90 μm. This configuration may improve current spreading, reduce operating voltage, and enhance brightness of the light-emitting device.

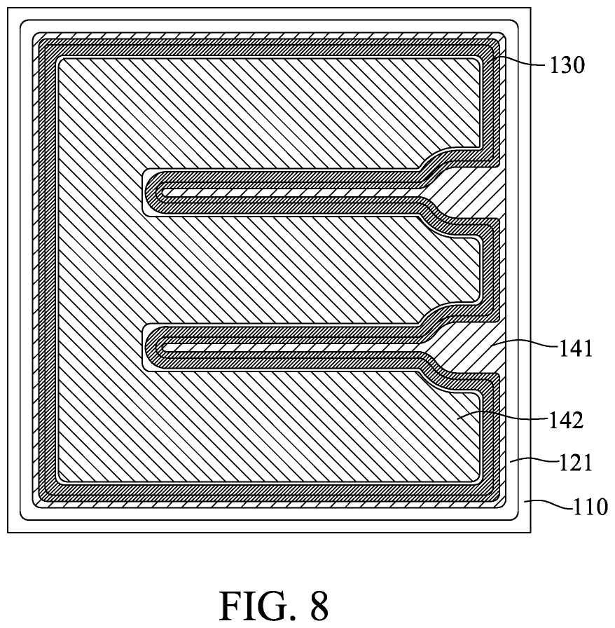

In another embodiment, referring to FIG. 8, the trench 130 is formed as a continuous groove that may extend along the first electrode 141, and the first electrode 141 has the extending portion that extends into the trench 130. The current flows through the path A and the path C that have different distances from the first electrode 141 to the active layer 122, thereby reducing current crowding.

In the embodiments shown in FIG. 5 to FIG. 7, as mentioned above, the light-emitting device may include a plurality of the trenches 130 that are spaced apart from each other. In these embodiments, a portion of the charge carriers injected through the mesa surface 126 may directly flow to the first semiconductor layer 121 through the path B (see FIG. 4). Therefore, the distance (H2) may be reduced and may range from 200 nm to 500 nm, for example, 300 nm. In the embodiment where the trench 130 is formed as a continuous groove, as shown in FIG. 8, the distance (H2) may range from 400 nm to 800 nm, for example, the distance (H2) may be 500 nm or 600 nm.

The first electrode 141 directly contacts the first semiconductor layer 121 which may be an n-type semiconductor layer, for example. The first electrode 141 includes one or more of chromium (Cr), platinum (Pt), gold (Au), nickel (Ni), titanium (Ti), and aluminum (Al). The first semiconductor layer 121 has a higher Al content, therefore, a connection between the first electrode 141 and the first semiconductor layer 121 needs to undergo a high-temperature fusion process after the first electrode 141 is disposed on the mesa surface 126 so as to form an alloy and establish a good ohmic contact between the first electrode 141 and the first semiconductor layer 121. The first electrode 141 may be a single-layer structure, a double-layer structure, or a multiple-layer structure, for example, a laminate structure of Ti/Al, Ti/Al/Au, Ti/Al/Ni/Au, Cr/Al/Ti/Au, or Ti/Al/Au/Pt.

The second electrode 142 is formed on the upper surface 124 and electrically connected to the second semiconductor layer 123 which is described as a p-type semiconductor layer as an example. The second electrode 142 may include a transparent conductive oxide material or a metallic material, for example, a metal alloy such as NiAu, NiAg, and NiRh. In certain embodiments, the second electrode 142 has a thickness of less than 30 nm so as to minimize light absorption. In certain embodiments, the active layer 122 emits light with a wavelength of less than 280 nm. The second electrode 142 is an indium tin oxide (ITO) layer with a thickness ranging from 5 nm to 20 nm. For example, the ITO layer (i.e. the second electrode 142) has a thickness ranging from 10 nm to 15 nm, and accordingly has a reduced absorption rate for light emitted by the active layer 122, e.g., below 40%.

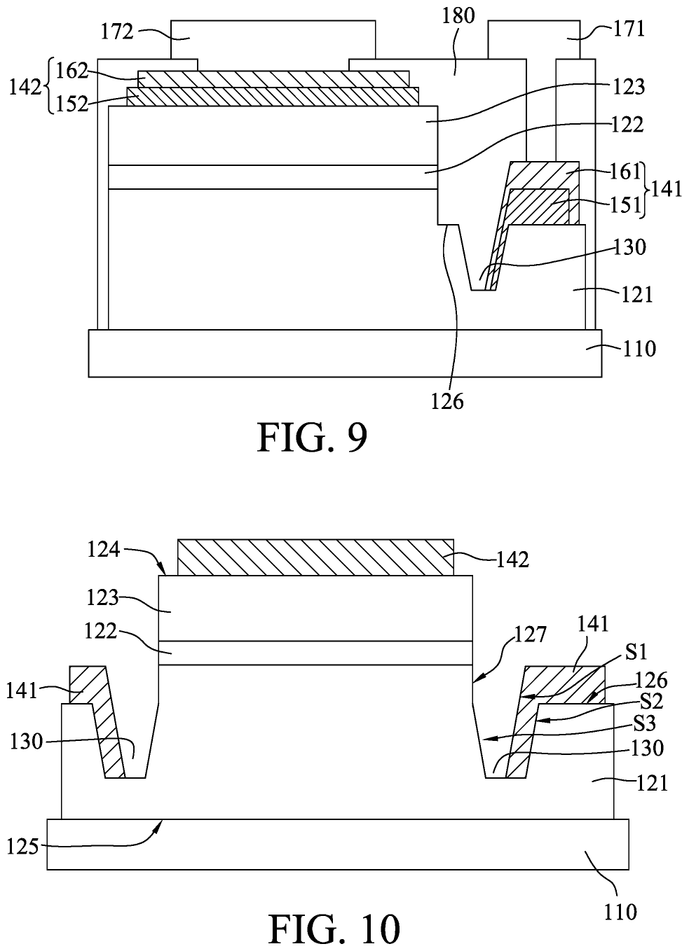

In some embodiments, the light-emitting device may be a flip-chip light-emitting device. As shown in FIG. 9, the first electrode 141 includes a first contact electrode 151 and a first connect electrode 161. The first contact electrode 151 is partially disposed within the trench 130 and directly contacts the first semiconductor layer 121 (the n-type semiconductor layer). The first connect electrode 161 is partially disposed within the trench 130 and is connected to the first contact electrode 151. The second electrode 142 includes a second contact electrode 152 and a second connect electrode 162. The second contact electrode 152 directly contacts the second semiconductor layer 123 (the p-type semiconductor layer), and the second connect electrode 162 is connected to the second contact electrode 152. In certain embodiments, each of the first and second connect electrode 161, 162 may be a multi-layer metallic laminate including, for example, an adhesion layer and a conductive layer disposed in such order on a respective one of the first and second contact electrode 151, 152. The adhesion layer may be a Cr metal layer and have a thickness ranging from 1 nm to 10 nm. The conductive layer may be an Al metal layer and may have a thickness not less than 100 nm, for example, ranging from 200 nm to 500 nm. The Al metal layer not only has good conductivity, but also higher reflectivity of ultraviolet light. In certain embodiments, the conductive layer has a reflectivity of more than 70% of light emitted by the active layer 122. Furthermore, the conductive layer may include an Al layer and a stress buffer layer, for example, an alternating Al/Ti laminate. In addition, some other layers such as an etch stop layer (e.g., Pt layer) or a bonding layer (e.g., Ti layer) may be formed on the conductive layer. In certain embodiments, the first connect electrode 161 may completely cover the first contact electrode 151 so as to increase a height of the first electrode 141 and protect the first contact electrode 151.

The light-emitting device may further include an insulating layer 180 that covers the first and second electrodes 141, 142, exposed surfaces of the semiconductor laminate 120 and the trench 130 such that the first connect electrode 161 and second connect electrode 162 are isolated. The insulating layer 180 has openings to expose a portion of the first connect electrode 161 and a portion of the second connect electrode 162. The insulating layer 180 includes a non-conductive material. In certain embodiments, the non-conductive material may be an inorganic material or a dielectric material. The inorganic material includes silica gel or glass. The dielectric material includes aluminum oxide, silicon nitride, silicon oxide, titanium oxide, or magnesium fluoride. For example, the insulating layer 180 may include silicon dioxide, silicon nitride, titanium oxide, tantalum oxide, niobium oxide, barium titanate, or combinations thereof. The insulating layer 180 may include, for example, a distributed Bragg reflector (DBR) that is formed from at least two of the aforesaid materials that are alternately disposed. In some embodiments, the insulating layer 180 may be a reflective insulating layer. As shown in FIG. 9, the light-emitting device has a relatively larger area for light emission, and the second connect electrode 162 only partially covers the second contact electrode 152. Therefore, having the insulating layer 180 as a highly reflective structure may be conducive for the light-emitting device to have improved light extraction efficiency.

As shown in FIG. 9, the light-emitting device further includes a first electrode pad 171 and a second electrode pad 172 that are located on the insulating layer 180 and connected to the first connect electrode 161 and the second connect electrode 162 through the openings of the insulating layer 180, respectively. The first electrode pad 171 and the second electrode pad 172 may be formed from the same material by the same process, and may be formed simultaneously by patterning a pad layer. The first and second electrode pads 171, 172 may be made of a material selected from one or more of Cr, Pt, Au, Ni, Ti, Al, and AuSn.

FIG. 10 illustrates a variation of the light-emitting device according to the embodiment of FIG. 2A. Similarly, the trench-defining wall of each of the trenches 130 has the first region (S2) that is away from the connecting surface 127 and the second region (S3) that is closer to the connecting surface 127 than the first region (S2). In this variation, the second region (S3) is directly connected to the connecting surface 127 as shown in FIG. 10. That is, the distance (d2) between the second region (S3) and the connecting surface 127 is 0 μm. This configuration may further reduce travelling distance for current flow to some extent.

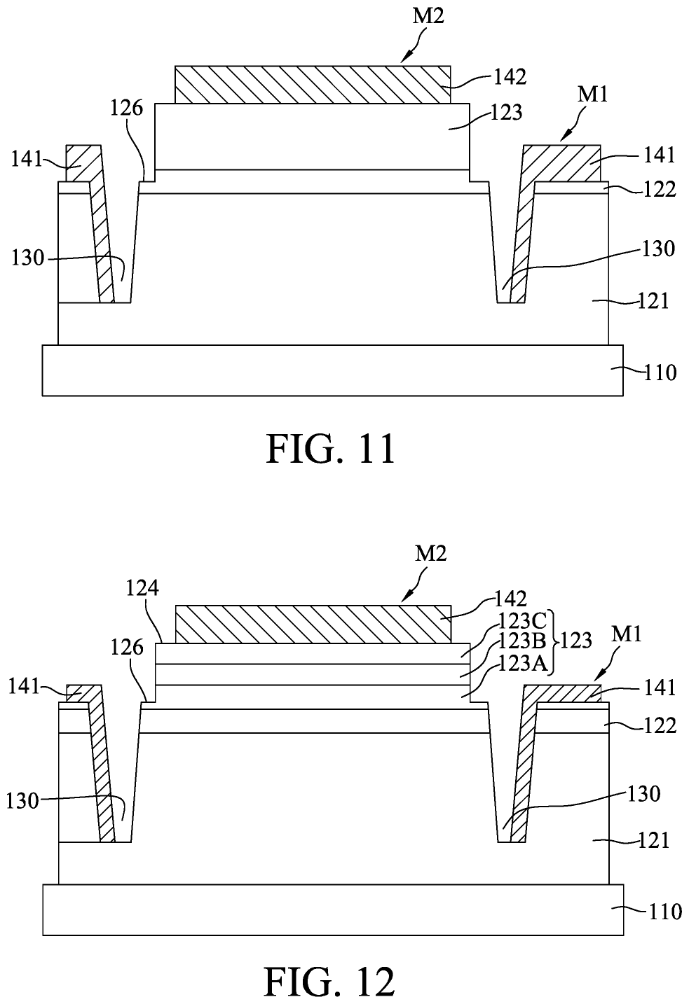

FIG. 11 shows another embodiment of the light-emitting device according to the present disclosure, which has a structure similar to that of the embodiment shown in FIG. 2A except for the mesa surface 126, the trench 130, and constructions corresponding thereto. Specifically, the trench 130 in this embodiment is formed as a continuous groove (as shown in FIG. 8) and the mesa surface 126 is constituted by the active layer 122. That is, there is the entire thickness of the first semiconductor layer 121 and a partial thickness of the active layer 122 under the mesa surface 126. Moreover, the active layer 122 may be doped with an n-type dopant, such as Si, and may have a doping concentration of 1×10¹⁸/cm³ or more, for example, ranging from 1×10¹⁸/cm³ to 1×10¹⁹/cm³, such as 2×10¹⁸/cm³ or 5×10¹⁸/cm³, etc.

In the present embodiment, by doping the active layer 122 with an appropriate amount of n-type dopant, the electron concentration of the active layer 122 may be increased, thereby improving internal quantum efficiency. Meanwhile, due to the doping, the first electrode 141 may have good ohmic contact with the active layer 122. In one embodiment, the active layer 122 has a band gap that is lower than a band gap of the first semiconductor layer 121, which is more conducive for the first electrode 141 to form a good ohmic contact with the active layer 122 on the mesa surface 126.

In one embodiment, the semiconductor laminate 120 may include a confinement layer (not shown) that is located between the active layer 122 and the second semiconductor layer 123. In certain embodiments, the confinement layer has a higher Al content, is either low-doped or undoped, and has a thickness no greater than 50 nm. This configuration may restrict the diffusion of the dopant from the second semiconductor layer 123 into the active layer 122, thereby enhancing optoelectronic performance of the light-emitting device.

In the present embodiment, the trench 130 is formed as a continuous groove, which may divide the semiconductor laminate 120 into two portions, i.e., a first portion (M1) and a second portion (M2). The active layer 122 that is located in the first portion (M1) is completely separated from the active layer 122 that is located in the second portion (M2). This configuration increases the distance from the mesa surface 126 to the lower surface 125, thereby enhancing the injection efficiency of the charge carriers and their spread in the first semiconductor layer 121.

FIG. 12 shows a yet another embodiment of the light-emitting device according to the present disclosure, which has a structure similar to that of the embodiment shown in FIG. 11 except for the mesa surface 126, and constructions corresponding thereto. Specifically, the mesa surface 126 is constituted by the second semiconductor layer 123. That is, the first portion (M1) of the semiconductor laminate includes the entire thickness of the first semiconductor layer 121, the entire thickness of the active layer 122, and a partial thickness of the second semiconductor layer 123. Moreover, the second semiconductor layer 123 is doped with a p-type dopant and may include a first highly doped sub-layer 123A, an electron blocking sub-layer 123B, and a second highly doped sub-layer 123C that are arranged in such order on the active layer 122. The first highly doped sub-layer 123A is located between the electron blocking sub-layer 123B and the active layer 122, and acts as an ohmic contact layer and a hole injection layer for the first electrode 141. The first highly doped sub-layer 123A has a doping concentration of 1×10¹⁹/cm³ or more, for example, ranging from 1×10¹⁹/cm³ to 5×10¹⁹/cm³. The electron blocking sub-layer 123B has a doping concentration of 1×10¹⁷/cm³ or more, for example, ranging from 1×10¹⁸/cm³ to 1×10¹⁹/cm³. The second highly doped sub-layer 123C has a doping concentration of 5×10¹⁹/cm³ or more, for example, ranging from 5×10¹⁹/cm³ to 5×10²¹/cm³.

The electron blocking sub-layer 123B has a band gap that is greater than band gaps of the first highly doped sub-layer 123A and the second highly doped sub-layer 123C. Accordingly, the mesa surface 126 is arranged to be lower than the electron blocking sub-layer 123B as shown in FIG. 12, i.e., the first portion (M1) of the semiconductor laminate 120 does not include any of the electron blocking sub-layer 123B, so that charge carriers injected from the mesa surface 126 are not blocked by the electron blocking sub-layer 123B, thereby improving the injection efficiency. In one embodiment, a height difference between the mesa surface 126 and the upper surface 124 of the semiconductor laminate 120 is greater than 50 nm but not greater than 500 nm, for example, may be greater than 50 nm and less than 200 nm, or ranging from 200 nm to 500 nm.

In the present embodiment, similar to the aforementioned embodiment shown in FIG. 11, the portion of the active layer 122 that is located in the first portion (M1) is completely separated from the portion of the active layer 122 that is located in the second portion (M2) by the continuous trench 130. In the present embodiment, the mesa surface 126 is arranged at the same height as a level within the second semiconductor layer 123 and constituted by the first highly doped sub-layer 123A that is adjacent to the active layer 122. In this configuration, the portion of the first highly doped sub-layer 123A that is located in the first portion (M1) may provide an electrode contact surface on which the first electrode 141 is formed so that good ohmic contact is formed between the first highly doped sub-layer 123A and the first electrode 141. On the other hand, the portion of the first highly doped sub-layer 123A that is located in the second portion (M2) may act as a hole injection layer which may improve hole injection efficiency.

In this embodiment, since the first electrode 141 is formed on the first highly doped sub-layer 123A, the first electrode 141 may be formed from the same material as the second electrode 142, which may be conducive for forming an ohmic contact with an n-type AlGaN semiconductor layer. Furthermore, a reduced height difference between the upper surface 124 of the semiconductor laminate 120 and the mesa surface 126 is advantageous for forming the first and second electrode pads 171, 172 that can potentially withstand more pushing/pulling stress on the upper surface 124 and the mesa surface 126 of the semiconductor laminate 120. Consequently, the resulting light-emitting device exhibits better mechanical strength and reliability.

The disclosure further provides a lighting apparatus that includes at least one of the light-emitting device according to the aforesaid embodiments.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device comprising:
a semiconductor laminate having a mesa surface, an upper surface, a connecting surface that connects said upper surface and said mesa surface, and a lower surface opposite to said mesa surface and said upper surface, said semiconductor laminate including a first semiconductor layer, an active layer, and a second semiconductor layer disposed in such order in a direction from said lower surface to said upper surface, and having at least one trench that extends from said mesa surface into said first semiconductor layer;
a first electrode electrically connected to said first semiconductor layer, said first electrode being formed on said mesa surface and having an extending portion that extends into said trench; and
a second electrode electrically connected to said second semiconductor layer and formed on said upper surface.

2. The light-emitting device of claim 1, wherein said at least one trench is formed as a continuous groove.

3. The light-emitting device of claim 1, wherein said at least one trench is defined by a trench-defining wall that has a first region (S2) which is away from said connecting surface and which is covered by said extending portion, said extending portion having an extending wall (S1) away from said trench-defining wall, said first electrode having an upper surface that is opposite to said mesa surface 126 and that is connected to said extending wall (S1), said extending wall (S1) being separated from said first region (S2) of said trench-defining wall by a distance (d1) less than a width (L1) of said upper surface of said first electrode.

4. The light-emitting device of claim 3, wherein said trench-defining wall further has a second region (S3), that is closer to said connecting surface than said first region (S2), said second region (S3) being spaced apart from said connecting surface by a distance (d2).

5. The light-emitting device of claim 4, wherein said second region (S3) is spaced apart from said extending wall (S1) of said first electrode by a distance (d3).

6. The light-emitting device of claim 1, wherein said at least one trench has a bottom that is distal from said mesa surface, said bottom being separated from said lower surface of said semiconductor laminate by a distance (H2) that is ⅕ to ½ of a thickness of said first semiconductor layer.

7. The light-emitting device of claim 1, wherein said at least one trench extends from said mesa surface into said first semiconductor layer by a depth (H1) that is greater than 100 nm.

8. The light-emitting device of claim 1, wherein a projection of said first electrode on said lower surface partially overlaps a projection of said at least one trench on said lower surface, an overlapping area where the projection of said first electrode overlaps the projection of said at least one trench is 5% to 70% of the projection of said first electrode.

9. The light-emitting device of claim 1, wherein a projection of said at least one trench on said lower surface has an area that is 5% to 60% of an area of said mesa surface.

10. The light-emitting device of claim 1, wherein a projection of said at least one trench on said lower surface has a shape of a square, a circle, or an ellipse.

11. The light-emitting device of claim 1, wherein said at least one trench has an opening at said mesa surface, said opening having a width that ranges from 1 to 50 μm.

12. The light-emitting device of claim 1, wherein said at least one trench has an opening at said mesa surface, and a bottom opposite to said opening, said opening being greater in size than said bottom of said trench.

13. The light-emitting device of claim 1, wherein said at least one trench has a cross section in the direction, said cross section having a trapezoidal shape, said trench-defining wall having an inclined angle that is less than 90 degrees.

14. The light-emitting device of claim 1, wherein said at least one trench includes a plurality of trenches that are uniformly spaced apart from each other, distributed with progressively narrowing spacing or distributed with progressively widening spacing.

15. The light-emitting device of claim 1, wherein said at least one trench includes a plurality of trenches, and, when viewing said first electrode and said trenches from above said light-emitting device, said first electrode has a corner portion, and said trenches are positioned near said corner portion.

16. The light-emitting device of claim 1, wherein:
said first electrode has at least one corner portion;
said at least one trench includes a plurality of trenches; and
when viewing said first electrode and said trenches from above said light-emitting device, said trenches are arranged along said first electrode, and said trenches are spaced increasingly further apart as said trenches are positioned progressively further away from said at least one corner portion.

17. The light-emitting device of claim 16, wherein, at a position near said corner portion, two adjacent ones of said trenches are spaced apart by a distance ranging from 1 to 40 μm.

18. The light-emitting device of claim 16, wherein, at a position away from said corner portion, two adjacent ones of said trenches are spaced apart by a distance ranging from 5 to 100 μm.

19. The light-emitting device of claim 1, wherein said first electrode has a strip portion.

20. A lighting apparatus, comprising a light-emitting device according to claim 1.
